(19) United States
(12) Patent Application Publication
(10) Pub. No.: US 2012/0173938 A1
(43) Pub. Date: Jul. 5, 2012

(54) SCAN CELL DESIGNS WITH SERIAL AND PARALLEL LOADING OF TEST DATA

(76) Inventor: Sreejit Chakravarty, Mountain View, CA (US)

(21) Appl. No.: 12/982,634

(22) Filed: Dec. 30, 2010

(51) Int. Cl. G01R 31/3177; G06F 11/25

(52) U.S. Cl. 714/726; 714/E11.155

(57) ABSTRACT

A scan cell includes first, second and third data inputs and a control input. The first, second and third data inputs are configured to receive respective first, second and third data bits. The control input is configured to receive a control signal. Latching logic is configured to latch an input value to a scan cell output. Selection logic is configured to select the input value from between the first, second and third data bits, depending on a state of the control signal.

### CROSS-REFERENCE TO RELATED APPLICATIONS

This application is related to U.S. patent application Ser. No. ______ (attorney docket No. L09-0408US2) filed concurrently with the present application and incorporated herein by reference.

### TECHNICAL FIELD

This application is directed, in general, to an electronic device, and, more specifically, to testing thereof.

### BACKGROUND

A complex integrated circuit (IC) device often includes test circuitry. Such circuitry may be used to test the device at the end of the manufacturing line, or may be used after the device is shipped and installed by a system integrator to ensure continued proper operation of the device.

A scan chain is sometimes used in the test circuitry. The scan chain typically includes a number of scan cells arranged such that a scan cell at a later stage of the chain receives the output of a scan cell at an earlier stage of the chain. A multiplexer located between the scan cells receives the prior cell's output and a functional bit from device logic that may be tested using the scan chain. When a scan is enabled, the multiplexer selects the output of the previous scan cell for input to the later scan cell. When the scan is disabled, the multiplexer selects the functional bit. Thus, test data may be serially loaded into the scan chain, and input to the logic under test. Internal values produced by the logic under test may then be serially shifted out of the scan chain for evaluation.

### SUMMARY

One aspect provides a scan cell. The scan cell includes first, second and third data inputs and a control input. The first, second and third data inputs are configured to receive respective first, second and third data bits. The control input is configured to receive a control signal. Latching logic is configured to latch an input value to a scan cell output. Selection logic is configured to select the input value from between the first, second and third data bits, depending on a state of the control signal.

Another embodiment provides an integrated circuit (IC). The IC includes a functional block and a scan cell coupled thereto. The scan cell includes first, second and third data inputs and a control input. The first, second and third data inputs are configured to receive respective first, second and third data bits. The first data bit is received from the functional block. The control input is configured to receive a self-test signal. Latching logic is configured to latch an input value to a scan cell output. Selection logic is configured to select the input value from between the first, second and third data bits depending on a state of the self-test signal.

Another embodiment is a method of forming an integrated circuit. The method includes forming over a semiconductor substrate a scan cell that includes first, second and third data inputs. The first, second and third data inputs are configured to receive respective first, second and third data bits. Latching logic is configured to receive an input value at a latch input and to latch the input value to a scan cell output. Selection logic is configured to receive a self-test signal and to select the input value from between the first, second and third data bits depending on a state of the self-test signal.

Yet another embodiment is a library of standard logic elements. The library includes a standard logic element corresponding to a scan cell. The scan cell includes first, second and third data inputs and a control input. The first, second and third data inputs are configured to receive respective first, second and third data bits. The control input is configured to receive a control signal. Latching logic is configured to latch an input value to a scan cell output. Selection logic is configured to select the input value from between the first, second and third data bits, depending on a state of the control signal.

### BRIEF DESCRIPTION

Reference is now made to the following descriptions taken in conjunction with the accompanying drawings, in which:

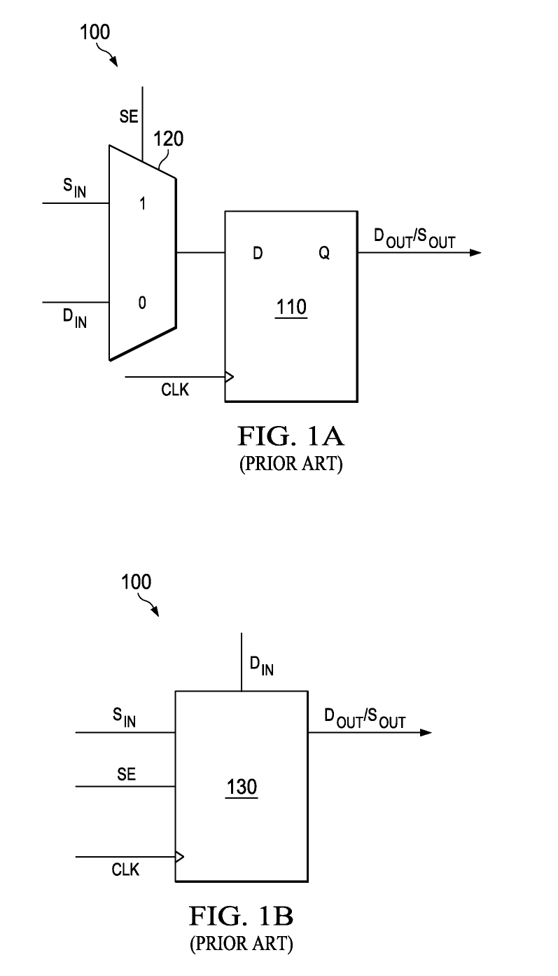

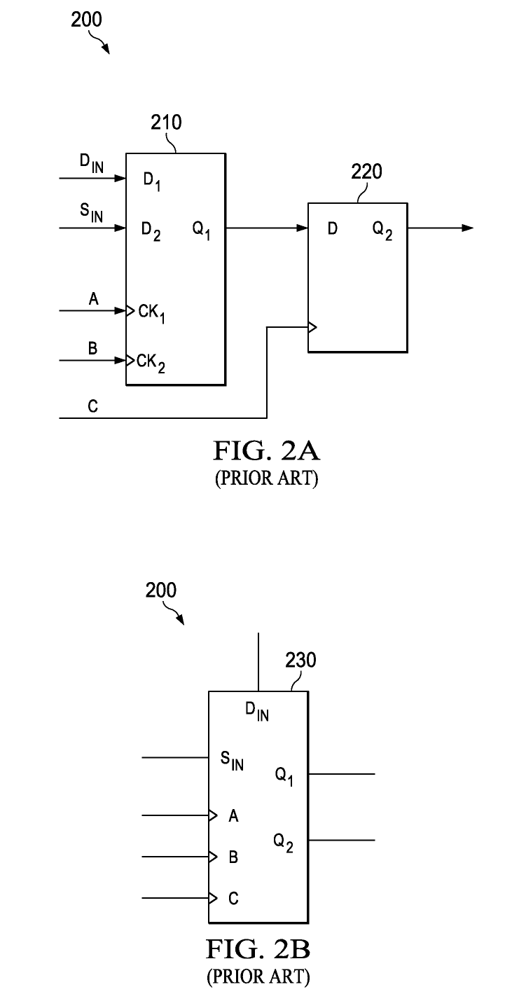

FIGS. 1A, 1B, 2A and 2B illustrate prior art scan cells;

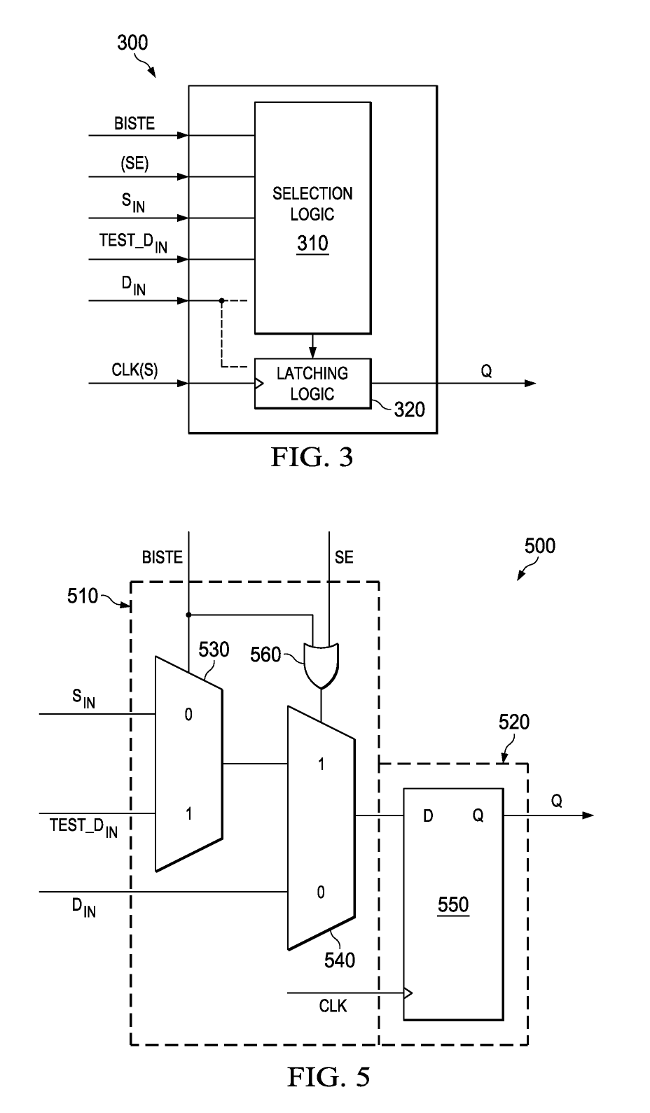

FIG. 3 illustrates a scan cell of the disclosure;

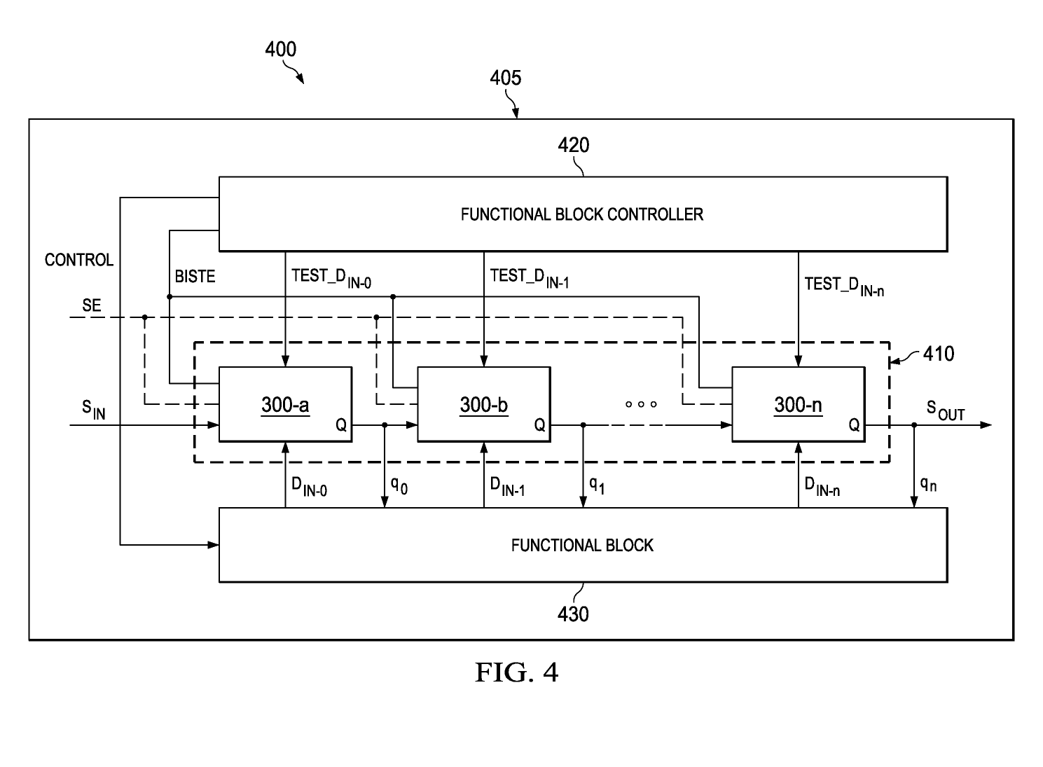

FIG. 4 illustrates an integrated circuit including a functional block test system of the disclosure;

FIG. 5 illustrates an embodiment of the scan cell of FIG. 3 using a D-type flip-flop;

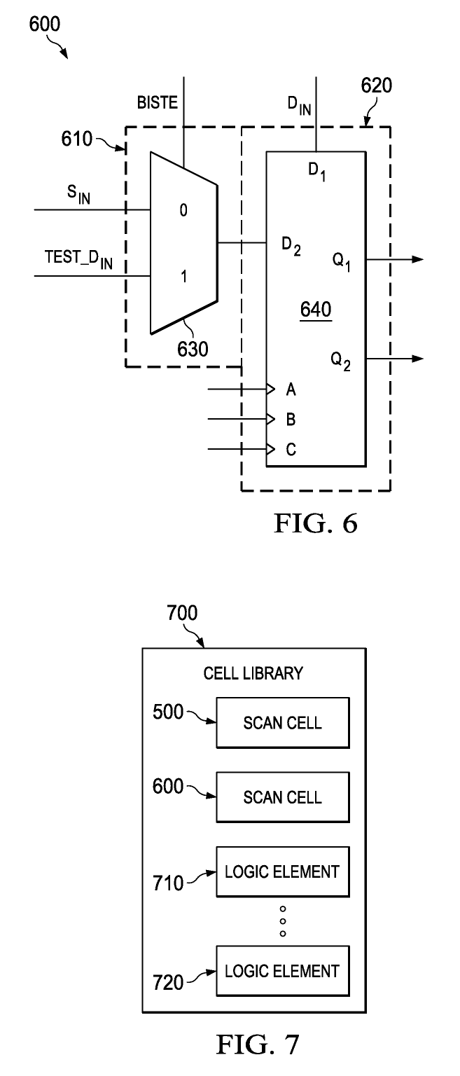

FIG. 6 illustrates an embodiment of the scan cell using a two-phase clocked flip-flop;

FIG. 7 illustrates a cell library that includes scan cells, e.g. the scan cells of FIGS. 5 and 6; and

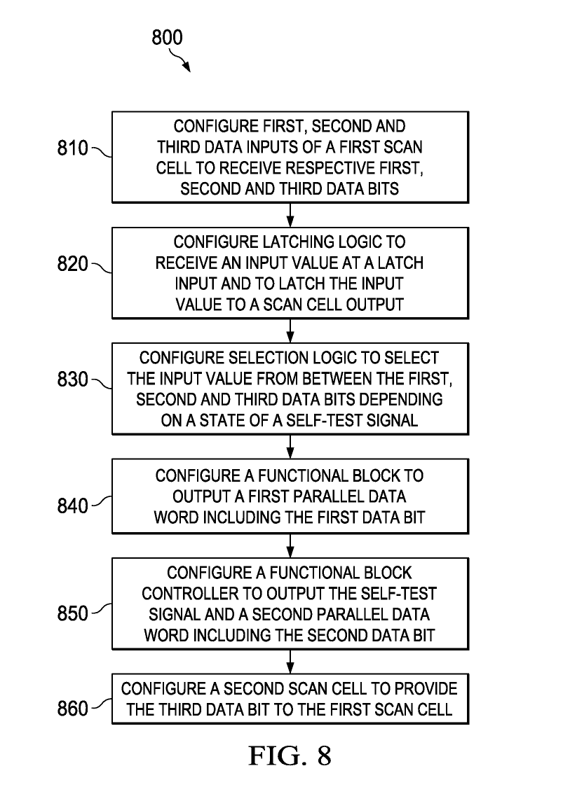

FIG. 8 illustrates a method of forming an integrated circuit.

### DETAILED DESCRIPTION

Herein a digital signal may be equivalently described having a value of TRUE or “1”. A digital signal may also be equivalently described having a value of FALSE or “0”. Herein when an input to a logical element is described as being “configured” to receive a particular input, the input may include any number of gates, transistors or interconnects suitably configured to provide the desired input functionality. Herein a data bit is a bit of a serial data stream or a parallel data word that conveys information, as opposed to a clock or a control bit that exerts control over the function of one or more logic elements such as a multiplexer. Herein a multiplexer delay is a delay subjected on a data bit presented at a data input of a multiplexer. A multiplexer is any combination of gates, transistors, interconnects, etc. configured to select between first and second data inputs under the control of a selector control signal presented at a selector input. Herein a data input is an input configured to receive a data bit, as opposed to a selector signal or a clock signal. Herein, a signal may be referred to as “asserted” or “unasserted”. An asserted signal is one that has a logic value selected to result in a stated effect. The signal may be referred to as unasserted when the signal has a logic value that does not result in the stated effect. An asserted signal may be a logical “1” or a logical “0” depending on the specific configuration of logical elements.

Scan chains are conventionally used at the end of a manufacturing line to test various portions of an IC device. Test data provided by an end-of-line tester may be serially shifted into the scan chain. Internal functional data that results from the test data may be loaded into the scan chain. The internal data may then be serially shifted out of the scan chain and evaluated.

In some cases, however, it may also be desirable to test a functional block, e.g. a memory or combinatorial logic, of the device after the device has shipped to a customer. Conventionally such testing may be done using built-in self-test (BIST) circuitry that includes a BIST engine designed to provide various test vectors to the functional block to ensure accurate operation. The test vectors are typically provided in the form of parallel data, such as a word of data to be loaded into a memory. In such cases it may be desirable or necessary to integrate the BIST circuitry with the scan chain. It may also be desirable or necessary to retain the ability to provide test data to the functional block in serial fashion via a scan chain to provide end-of-line test capability. However, conventional scan chains are not equipped to accommodate both serial and parallel data without increasing the latency of a critical data path.

This disclosure includes embodiments that provide the novel ability of a scan chain to support both serial and parallel loading of test data without increasing critical data latency. Thus, a single scan chain may support both end-of-line testing and BIST testing without reducing performance of the IC during normal operation. Self-test of the functional block after installation of the IC is therefore possible with little or no performance penalty and without the need for redundant test circuitry.

Turning to FIG. 1A, a multiplexing scan cell 100 representative of some conventional designs is illustrated. The scan cell 100 includes a D-type flip-flop 110 and a multiplexer 120. The multiplexer 120 receives an S_{IN} (serial_in) bit and a D_{IN} (data_in) bit at its data inputs. Typically the S_{IN} bit is received from a previous scan cell in a scan chain in which the scan cell 100 operates. When an SE (scan-enable) signal is asserted (e.g. TRUE) the multiplexer 120 selects the S_{IN} bit for input to the flip-flop 110. When SE is unasserted (e.g. FALSE), the multiplexer 120 selects the D_{IN} bit for input to the flip-flop 110. A CLK signal latches the output of the multiplexer 120 to the Q output of the flip-flop, with the S_{IN} bit being output as S_{OUT}, and the D_{IN} bit being output as D_{OUT}.

FIG. 1B illustrates a functional abstraction 130 of the scan cell 100. The functional abstraction 130 may be implemented as an element of a library of standard logic elements. In this representation, the scan cell 100 appears as a single functional block with two data inputs for S_{IN} and D_{IN}, a selector input for SE, and a clock input. A single output provides the selected S_{OUT} or D_{OUT} bit.

FIG. 2A illustrates another conventional scan cell 200 design, referred herein as a two-port latch design. A two-port latch 210 receives the D_{IN} bit at a first D input, D₁. The D_{IN} bit is clocked through to a Q₁ output upon the active edge of an “A” clock at a CK₁ input. The latch 210 receives the S_{IN} bit at a second D input D₂. The S_{IN} bit is clocked through to the Q₁ output upon the active edge of a “B” clock at a CK₂ input. The Q₁ output is clocked through to a Q₂ output of a D flip-flop 220 upon the active edge of a “C” clock.

FIG. 2B illustrates a functional abstraction 230 of the scan cell 200. The functional abstraction 230 may also be implemented as an element of a library of standard logic elements. In this representation, the scan cell 200 appears as a single functional block with two data inputs for S_{IN} and D_{IN}, three clock inputs A, B and C, and two outputs Q₁ and Q₂.

FIG. 3 illustrates a scan cell 300 of the disclosure. The scan cell 300 differs from the scan cells 100, 200 by including an input to receive a BIST enable (BISTE), or self-test, signal. Some embodiments also include an SE input, the presence of which depends, as discussed further below, on the particular internal configuration of the scan cell 300. The scan cell 300 further differs from the scan cells 100, 200 by including three data inputs, S_{IN}, D_{IN} and test_D_{IN}.

Selection logic 310 receives the BISTE input, S_{IN}, and test_D_{IN} signals, and optionally the SE signal, if present. The latching logic 320 receives one or more clocks, represented as CLK(s). In some embodiments the selection logic 310 receives the D_{IN} signal, while in other embodiments the latching logic receives the D_{IN} signal. A dashed line denotes the optional routing of the D_{IN} signal in FIG. 3. In some embodiments the selection logic 310 determines which of S_{IN}, test_D_{IN}, and D_{IN} to present at an output Q of the scan cell 300, and in some embodiments the selection logic 310 and the latching logic 320 cooperate to determine which signal to present at the output Q. The determination is based at least on the state of BISTE, and in some embodiments based further on the state of SE and/or the CLK(s). The operation of the scan cell 300 is described further by various embodiments that follow. Advantageously the selection logic 310 is configured such that the data provided by the D_{IN} input are subjected to little or no additional latency relative to a conventional scan cell such as the scan cells 100, 200. This aspect is described in detail below.

FIG. 4 illustrates an IC 400 of the disclosure. The IC 400 includes a substrate 405 and a scan chain 410 located thereover that includes a number of scan cells 300, designated 300-a, 300-b . . . 300-n. The operation of the scan chain 410 is described for the case that the scan cells 300 are as described by a scan cell 500 described in FIG. 5. Each scan cell 300 receives the BISTE signal from a functional block controller 420. In embodiments exemplified by the scan cell 500 each scan cell 300 receives the SE signal from a scan controller (not shown). Some embodiments employ a scan cell design exemplified by a scan cell 600 is FIG. 6. In such embodiments the function of the SE signal is replaced by appropriate phasing of the A and B clock signals. Those skilled in the pertinent art are capable of making the necessary modifications.

A serial scan bit sequence S_{IN} enters the scan chain 410 via the scan cell 300-a. The Q output of each scan cell 300 is received by the selection logic 310 (FIG. 3) of the following scan cell 300, with the exception of the terminal scan cell 300-n which provides an output serial bit sequence via S_out. Each scan cell 300 receives a corresponding test_D_{IN} bit from the functional block controller 420.

Each scan cell 300 additionally receives a corresponding D_{IN} bit from a functional block 430 that is controlled by the functional block controller 420. The functional block 430 may be, e.g. a combinatorial logic block or a memory. During normal operation, the functional block 430 receives control signals (not shown) to store and retrieve data used within the IC 400.

During a test of the functional block 430, e.g. an end-of-line test, the SE signal is asserted and the S_{IN} path provides a serial bit sequence to load the scan chain 410 with a desired bit pattern. The bit pattern may be input in parallel to the functional block 430 via q₀, q₁, . . . qₙ. The scan chain 410 may subsequently retrieve in parallel a response pattern from the functional block 430. The response pattern may then be serially shifted out from the scan chain 410 via S_{OUT} for evaluation.

During a self-test, e.g. after installation in an end product, the functional block controller 420 may control the scan chain 410 to load parallel data therein, such as a 16-bit test vector. The functional block controller 420 may then control the functional block 430 to store the test vector output by the Q-outputs of the individual scan cells 300. The functional block controller 420 may further control the functional block 430 to retrieve a response vector therefrom and store the individual bits of the response vector in each corresponding scan cell 300. The response vector may then be serially scanned out of the scan cell for evaluation by the functional block controller 420 or other means.

FIG. 5 illustrates an embodiment of the scan cell 500, referred to earlier, that is based on a multiplexer cell design and may be employed for the scan cell 300. Those skilled in the pertinent art will appreciate that the function of the illustrated scan cell 500 may be implemented by, e.g. discrete transistors, gates and logic elements other than those illustrated. Any such circuits that provide equivalent operation to that described and/or claimed is within the scope of the disclosure.

In the illustrated embodiment the scan cell 500 includes selection logic 510 and latching logic 520. The selection logic 510 includes a first multiplexer 530 and a second multiplexer 540. The latching logic 520 includes a D flip-flop 550. The first multiplexer 530 selects between S_{IN} and test_D_{IN} under control of the BISTE signal. For example, the first multiplexer 530 may be configured to select S_{IN} when BISTE is unasserted (e.g. FALSE) and test_D_{IN} when BISTE is asserted (e.g. TRUE). The second multiplexer 540 selects between the output of the first multiplexer 530 and the D_{IN} bit under control of SE and BISTE. Thus, the D_{IN} bit is subject to only a single multiplexer delay before the latching logic, while the S_{IN} and test_D_{IN} bits are subjected to two multiplexer delays. An OR gate 560 and the second multiplexer 540 are configured such that when either SE or BISTE are asserted, the output of the first multiplexer 530 (S_{IN} or test_D_{IN}) is selected for input to the flip-flop 550. When both SE and BISTE are unasserted the multiplexer 540 selects D_{IN} for input to the flip-flop 550.

Those skilled in the pertinent art will appreciate that the OR gate 560 may be implemented equivalently by a NOR gate or a De Morgan equivalent logic element. For example, the operation of the OR gate 560 and the multiplexer 540 may be provided by a NOR gate in combination with reversing the logical sense at the selector input to the multiplexer 540. In another example the OR gate may be replaced by a NAND gate with negated inputs, in combination with reversing the sense of the SE and BISTE signals and reversing the sense of the selector input to the multiplexer 540. For the purpose of the disclosure and the claims the OR gate encompasses these and any other logic elements that are configured to control the multiplexer 540 to select the output of the multiplexer 530 in the event that one or both of the BISTE and SE signals is asserted.

Advantageously the configuration of the scan cell 500 results in little or no additional latency of the D_{IN} signal relative to the conventional scan cell 100. Other possible configurations, such as for example selecting between the S_{IN} and D_{IN} signals using the first multiplexer 530, would add a multiplexer delay to the D_{IN} signal, increasing the critical path length of the D_{IN} signal and reducing the maximum clock speed of the IC 400. In contrast, the scan cell 500 advantageously shifts the additional multiplexer delay to the S_{IN} and test_D_{IN} signals. While the additional multiplexer delay of these signals may in some cases reduce the maximum possible rate of shifting in serial test data or loading parallel test data to the scan chain 410, in many cases it will be more desirable to accept the delay of these test signals while maintaining the full clock rate of the normal operation of the IC 400.

The embodiment of the selection logic 510 illustrated in FIG. 5 implements a logic function described the following truth table:

| BISTE | SE | D-Input |
|---|---|---|
| 0 | 0 | D_{IN} |
| 0 | 1 | S_{IN} |
| 1 | 0 | Test_D_{IN} |
| 1 | 1 | Test_D_{IN} |

By inspection of the truth table it is evident that:
The selection logic 510 selects the D_{IN} signal for input to the flip-flop 550 when BISTE and SE are both a same first logic value, e.g. FALSE.
The selection logic 510 selects the test_D_{IN} signal for input to the flip-flop 550 when BISTE and SE are both a same second logic value, e.g. TRUE, opposite the first logic value.
The selection logic 510 selects between the test_D_{IN} signal and the S_{IN} signal when BISTE has a different logic value from SE, e.g. when BISTE is FALSE and SE is TRUE and when BISTE is TRUE and SE is FALSE.

FIG. 6 illustrates another embodiment of a scan cell 600 that may be used as the scan cell 300. Those skilled in the pertinent art will appreciate that the function of the illustrated scan cell 600 may be implemented by, e.g. discrete transistors, gates and logic elements other than those illustrated. Any such circuits that provide equivalent operation to that described and/or claimed is within the scope of the disclosure.

In the illustrated embodiment the scan cell 600 includes selection logic 610 and latching logic 620. The selection logic 610 includes a multiplexer 630. The latching logic 620 includes a two-phase clocked flip-flop 640. The flip-flop 640 receives the D_{IN} signal via a D₁ input. The data presented at the D₁ input is clocked to the Q₁ output at an active edge of the A clock. The multiplexer 630 is configured to select between the S_{IN} and test_D_{IN} signals depending on the logic value of BISTE. For example, as illustrated the multiplexer 630 selects S_{IN} when BISTE is unasserted, and selects test_D_{IN} when BISTE is asserted. Thus, the D_{IN} bit is subject to no delay by the selection logic, while the S_{IN} and test_D_{IN} bits are subjected to a single multiplexer delay. The flip-flop 640 receives the output of the multiplexer 630 at a D₂ input. The output of the multiplexer 630 is clocked to the Q₁ output of the flip-flop 640 at an active edge of the B clock. The value of Q₁ is clocked to the Q₂ output at an active edge of the C clock. Thus, in the present embodiment the C clock does not play a role in determining which of S_{IN}, D_{IN} and test_D_{IN} appears at the Q₁ and Q₂ outputs, but shifts the value of the Q₁ output to the Q₂ output consistent with the operation of the functional abstraction 230 of FIG. 2.

As described with respect to the scan cell 500, the D_{IN} signal experiences little or no additional latency in the scan cell 600, as compared to the conventional scan cell 200. The S_{IN} and test_D_{IN} signals experience an additional multiplexer delay. But as described previously, it may be preferable that these signals are delayed so that the IC 400 may be clocked during normal operation at a greater clock frequency than possible if the D_{IN} signal were delayed.

The scan cells 500, 600 may be conveniently implemented as library cells in a library of standard logic elements used by an automated design tool. Those skilled in the pertinent art appreciate that automated design tools include various elements of a computational system, including data entry means such as keyboards, data storage elements such as disk drives, semiconductor memory and the like, computational elements such as processors and coprocessors, and networking means. The automated design tool may employ hard and soft macros to implement the various logic elements that are provided by the library.

FIG. 7 illustrates a cell library 700 that may include one or both of the scan cells 500, 600, as well as logic elements 710, 720 representative of other functional blocks that may be implemented in an IC design. An automated design tool may employ the cell library 700 to place any number of instances of the scan cells 500, 600 in the design of an IC such as the IC 400. Stitching routines may then configure the scan cells 500, 600 to form a scan chain such as the scan chain 410. The cell library 700 may exist independent of the automated design tool that implements the logic elements provided by the cell library 700. Thus, the cell library 700 may be physically embodied by a storage medium such as a magnetic or optical disk, or semiconductor memory. The cell library 700 may also be transferred via a network from one storage medium to another. For the purposes of the disclosure and the claims any copy of the cell library 700 that is created by transmitting an electronic representation of the cell library 700 from one storage medium to another is regarded as another instance of the cell library 700.

Turning to FIG. 8, illustrated is a method 800 of the disclosure for forming an integrated circuit. The method 800 is described without limitation with reference to the features described herein, e.g. of FIGS. 3-6. The steps of the method 800 may be performed in an order different from the illustrated order.

In a step 810, first, second and third data inputs of a first scan cell, e.g. the scan cell 300b, are configured to receive respective first, second and third data bits. In a step 820 latching logic is configured to receive an input value at a latch input and to latch the input value to a scan cell output. In a step 830 selection logic is configured to select the input value from between the first, second and third data bits depending on a state of a self-test signal.

In an optional step 840 a functional block, e.g. the functional block 430, is configured to output a first parallel data word including the first data bit. In an optional step 850 a functional block controller, e.g. the functional block controller 420, is configured to output the self-test signal and a second parallel data word that includes the second data bit. In an optional step 860, a second scan cell, e.g. the scan cell 300-a, is configured to provide the third data bit to the first scan cell.

Those skilled in the art to which this application relates will appreciate that other and further additions, deletions, substitutions and modifications may be made to the described embodiments.

What is claimed is:

1. A scan cell, comprising:
first, second and third data inputs configured to receive respective first, second and third data bits;
a first control input configured to receive a first control signal;
latching logic configured to latch an input value received at a latch input to a scan cell output; and
selection logic configured to select said input value from between said first, second and third data bits depending on a state of said first control signal.

2. The scan cell as recited in claim 1, wherein said selection logic includes a first multiplexer having a first data input configured to receive said first data bit and a second multiplexer having first and second data inputs configured to respectively receive said second and third data bits.

3. The scan cell as recited in claim 1, further comprising a second control input configured to receive a second control signal, wherein said selection logic is further configured to provide said input value by selecting said first data bit when said first and second control signals have a same first logic value.

4. The scan cell as recited in claim 3, wherein said selection logic is further configured to provide said input value by selecting said second data bit when said first and second control signals have a same logic value opposite said first logic value.

5. The scan cell as recited in claim 1, further comprising a second control input configured to receive a second control signal, wherein said selection logic is further configured to provide said input value by selecting between said second data bit and said third data bit when said first control signal has a different logic value from said second control signal.

6. The scan cell as recited in claim 1, further comprising a second control input configured to receive a second control signal, wherein said first and second control signals each have one of a first and a second logic value, and said selection logic is further configured to:
select said first data bit when both said first and second control signals have said first logic value;
select said second data bit when both said first and second control signals have said second logic value; and
select said third data bit when said first control signal has said first logic value and said second control signal has said second logic value.

7. The scan cell as recited in claim 2, further comprising a second control input configured to receive a second control signal, wherein:
said first multiplexer includes a first multiplexer output connected to said latch input, and a first selector input;
said second multiplexer includes a second multiplexer output connected to a second data input of said first multiplexer, and a second selector input configured to receive said first control signal; and
an OR gate has a first gate input connected to said second selector input, a second gate input configured to receive said second control signal, and a gate output connected to said first selector input.

8. An integrated circuit, comprising:
a functional block;
a scan cell coupled to said functional block, said scan cell including:
first, second and third data inputs configured to receive respective first, second and third data bits, said first data bit being received from said functional block;
a first control input configured to receive a self-test signal;
latching logic configured to latch an input value to a scan cell output; and
selection logic configured to select said input value from between said first, second and third data bits, depending on a state of said self-test signal.

9. The integrated circuit as recited in claim 8, wherein said selection logic includes a first multiplexer having said first data input, and a second multiplexer having said second and third data inputs.

10. The integrated circuit as recited in claim 8, further comprising a functional block controller configured to output a parallel test data word including said second data bit, to provide said self-test signal to said scan cell, and to control said functional block to output a parallel data word including said first data bit.

11. The integrated circuit as recited in claim 10, wherein said scan cell is a first scan cell, and further comprising a second scan cell configured to provide said third data bit to said first scan cell.

12. The integrated circuit as recited in claim 10, wherein said functional block is a memory.

13. The integrated circuit as recited in claim 10, further comprising a second control input configured to receive a scan-enable signal, wherein said selection logic is further configured to provide said input value by selecting said first data bit when said self-test and scan-enable signals have a same first logic value.

14. The integrated circuit as recited in claim 13, wherein said selection logic is further configured to provide said input value by selecting said second data bit when said self-test and scan-enable signals have a same second logic value opposite said first logic value.

15. The integrated circuit as recited in claim 10, further comprising a second control input configured to receive a scan-enable signal, wherein said selection logic is further configured to provide said input value by selecting between said second data bit and said third data bit when said self-test signal has a different logic value from said scan-enable signal.

16. The integrated circuit as recited in claim 9, further comprising a second control input configured to receive a scan-enable signal, wherein:
said first multiplexer includes a first multiplexer output connected to said latch input, and a first selector input; and
said second multiplexer includes a second multiplexer output connected to a second data input of said first multiplexer, and a second selector input configured to receive said self-test signal, and further comprising:
an OR gate having a first gate input connected to said second selector input, a second gate input configured to receive said scan-enable signal, and a gate output connected to said first selector input.

17. A method of forming an integrated circuit, comprising:
forming a first scan cell having first, second and third data inputs;
configuring said first, second and third data inputs to receive respective first, second and third data bits;
configuring latching logic to receive an input value at a latch input and to latch said input value to a scan cell output; and
configure selection logic to receive a self-test signal and to select said input value from between said first, second and third data bits depending on a state of said self-test signal.

18. The method as recited in claim 17, further comprising:
configuring a functional block to output a first parallel data word that includes said first data bit; and
configuring a functional block controller to output said self-test signal and a second parallel data word that includes said second data bit.

19. The method as recited in claim 17, wherein said functional block is a memory.

20. The method as recited in claim 17, wherein said selection logic is further configured to receive a scan-enable signal and to provide said input value by selecting said first data bit when said self-test and scan-enable signals have a same first logic value.

21. The method as recited in claim 20, wherein said selection logic is further configured to provide said input value by selecting said second data bit when said self-test and scan-enable signals have a same logic value opposite said first logic value.

22. The method as recited in claim 17, wherein said selection logic is further configured to receive a scan-enable signal and to provide said input value by selecting between said second data bit and said third data bit when said self-test signal has a different logic value from said scan-enable signal.

23. The method as recited in claim 17, wherein said selection logic includes:
a first multiplexer including:
a first selector input;
a first data input configured to receive said first data bit; and
a first multiplexer output connected to said latch input;
a second multiplexer including:
a second selector input configured to receive said self-test signal;
first and second data inputs configured to respectively receive said second and third data bits; and
a second multiplexer output connected to a second data input of said first multiplexer; and
an OR gate including:
a first gate input connected to said second selector input;
a second gate input configured to receive a scan-enable signal; and
a gate output connected to said first selector input.

24. A library of standard logic elements, comprising:
a standard logic element corresponding to a scan cell, including:
first, second and third data inputs configured to receive respective first, second and third data bits;
a first control input configured to receive a first control signal;
latching logic configured to receive an input value at a latch input and to latch said input value to a scan cell output; and
selection logic configured to select said input value from between said first, second and third data bits depending on a state of said first control signal.

25. The library as recited in claim 24, wherein said standard logic element further includes a second control input configured to receive a second control signal, said first and second control signals have first and second logic values, and said selection logic is further configured to:
select said first data bit when both said first and second control signals have said first logic value;
select said second data bit when said first control signal has said second logic value; and
select said third data bit when said first control signal has said first logic value and said second control signal has said second logic value.
